(19) United States
(12) Patent Application Publication
(10) Pub. No.: US 2016/0276429 A1
(43) Pub. Date: Sep. 22, 2016

(54) SEMICONDUCTOR DEVICE AND METHOD FOR FABRICATING THE SAME

(71) Applicant: United Microelectronics Corp., Hsin-Chu City (TW)

(72) Inventors: I-Ming Tseng, Kaohsiung City (TW); Wen-An Liang, Tainan City (TW); Rai-Min Huang, Taipei City (TW); Chen-Ming Huang, Taipei City (TW); Tong-Jyun Huang, Tainan City (TW); Kuan-Hsien Li, Tainan City (TW)

(21) Appl. No.: 14/684,445

(22) Filed: Apr. 13, 2015

(30) Foreign Application Priority Data
Mar. 18, 2015 (TW) 104108619

(51) Int. Cl. H01L 29/06; H01L 29/66; H01L 21/762; H01L 29/78; H01L 21/8234

(52) U.S. Cl. CPC H01L 29/0649; H01L 29/7851; H01L 21/823431; H01L 21/823481; H01L 21/76224; H01L 29/66545

(57) ABSTRACT

A semiconductor device and a method of forming the same, the semiconductor device includes a fin shaped structure, a spacer layer and a dummy gate structure. The fin shaped structure is disposed on a substrate, wherein the fin shaped structure has a trench. The spacer layer is disposed on sidewalls of the trench. The dummy gate structure is disposed across the trench and includes a portion thereof disposed in the trench.

### BACKGROUND OF THE INVENTION

1. Field of the Invention

The invention relates to a semiconductor device and a method of forming the same, and more particularly, to a semiconductor device having a dummy gate structure and a method of forming the same.

2. Description of the Prior Art

With the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the fin FET can be controlled by adjusting the work function of the gate.

However, integration of a metal gate and contact plugs still faces some issues in conventional FinFET fabrication. For instance, issues such as tiger tooth often arise when contact holes are formed with poor accuracy influencing the interconnection of contact plugs and overall performance of the device. Hence, how to improve the current FinFET fabrication and structure for resolving this issue has become an important task in this field.

### SUMMARY OF THE INVENTION

It is one of the primary objectives of the present invention to provide a semiconductor device and a method of forming the same, wherein the semiconductor device includes a dummy gate structure covering on edges of fin shaped structures such that it is sufficient to obtain a more reliable semiconductor device.

To achieve the purpose described above, the present invention provides a semiconductor device including a fin shaped structure, a spacer layer and a dummy gate structure. The fin shaped structure is disposed on a substrate, wherein the fin shaped structure has a trench. The spacer layer is disposed on sidewalls of the trench. The dummy gate structure is disposed across the trench and includes a portion thereof disposed in the trench.

To achieve the purpose described above, the present invention provides a method of forming a semiconductor device including the following steps. Firstly, a plurality of fin shaped structures is formed on a substrate. Next, a plurality of shallow trench isolations is formed in the substrate to surround the fin shaped structures. Then, a portion of the fin shaped structures is removed to form a trench across the fin shaped structures. Finally, a spacer layer is formed on sidewalls of the trench.

The semiconductor device and the forming method thereof in the present invention utilizes adjusting the forming time of the trench and selectively forming the spacer layer on the sidewalls of the trench to shrink the critical dimension of the trench, such that, one single dummy gate structure is allowed to stretch over the etched edges of two adjacent fin shaped structures and the trench between the two adjacent fin shaped structures, thereby dramatically increasing the device integration. Through such arrangement, it is sufficient to avoid the critical dimension of the trench opening being enlarged due to overreaction with or over-consumption by oxygen provided in the forming processes of the shallow trench isolation or the dielectric layer, such as the flowable chemical vapor deposition process or the thermal oxidization process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 4 are schematic diagrams illustrating a method of forming a semiconductor device according to a first embodiment of the present invention.

FIG. 5 to FIG. 6 are schematic diagrams illustrating a method of forming a semiconductor device according to a second embodiment of the present invention.

FIG. 7 to FIG. 10 are schematic diagrams illustrating a method of forming a semiconductor device according to a third embodiment of the present invention.

### DETAILED DESCRIPTION

To provide a better understanding of the present invention, preferred embodiments will be described in detail. The preferred embodiments of the present invention are illustrated in the accompanying drawings with numbered elements.

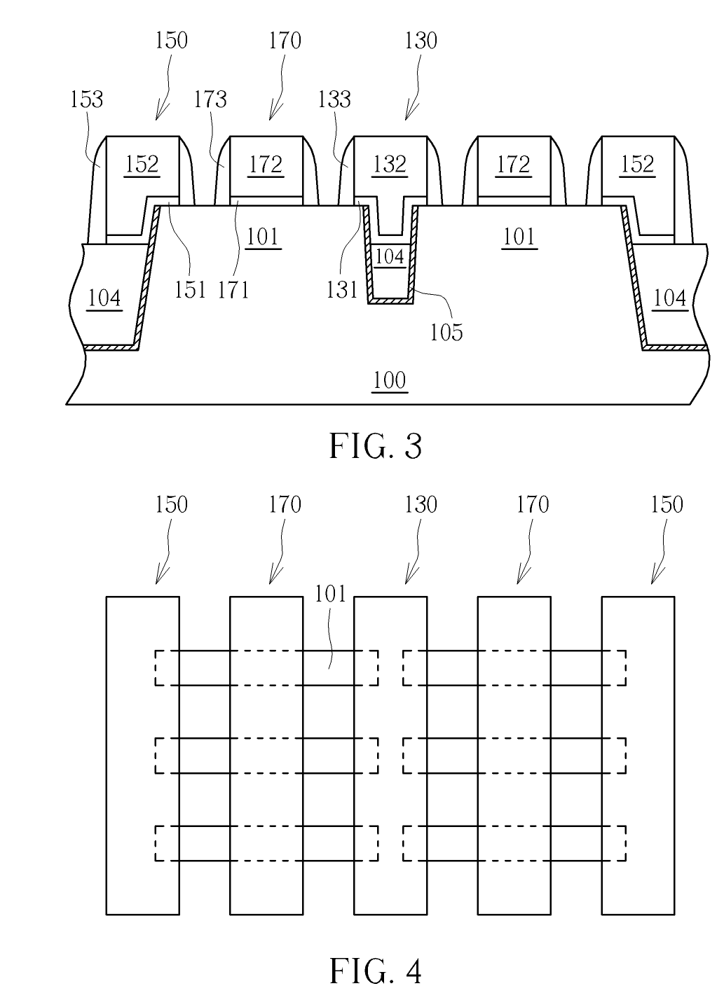

Please refer to FIG. 1 to FIG. 4, which are schematic diagrams illustrating a method of forming a semiconductor device according to the first embodiment of the present invention, wherein FIG. 4 shows a top view of the semiconductor device in forming steps. First of all, as shown in FIG. 1, a substrate 100 is provided, the substrate 100 for example includes a semiconductor substrate, such as a silicon substrate, a silicon-containing substrate or a silicon-on-insulator (SOI) substrate, and at least one fin shaped structure 101 is formed in the substrate 100. In an example of bulk silicon, the fin shaped structures 101 may be formed preferably through a sidewall image transfer (STI) process. The process may include forming a plurality of patterned sacrificial layers (not shown in the drawings) on the substrate 100 by using a photolithography and an etching process, performing a depositing and an etching processes sequentially to form a spacer (not shown in the drawings) at sidewalls of each of the patterned sacrificial layers, and then removing the patterned sacrificial layers and performing another etching process by using the spacer as a mask, thereby transferring the patterns of the spacer to a monolayered or a multilayered patterned mask 110, for example a composite mask structure consisted of a silicon oxide layer 111, a silicon nitride layer 112 and a silicon oxide layer 113. After that, another etching process is performed to transfer the patterns of the patterned mask 110 to the substrate 100 underneath, and to form a plurality of shallow trenches 102 and to define each fin shaped structure 101 simultaneously. Also, in another embodiment, a fin cut process may be further performed to form the fin shaped structures 101 according to the practical requirement, for example, the fin shaped structures 101 parallel to each other, as shown in FIG. 3.

Alternatively, in another embodiment, the formation of the fin shaped structures 101 may also be accomplished by first forming a patterned hard mask (not shown in the drawings) on the substrate 100, and then performing an epitaxial process on the exposed substrate 100 through the patterned hard mask to form a semiconductor layer (not shown in the drawings), such as silicon or silicon germanium layer. The semiconductor layer may then be used as the corresponding fin-shaped structure. Otherwise, in another embodiment, if the substrate is an SOI substrate (not shown in the drawing), the patterned mask 110 may be used to etch a semiconductor layer (not shown in the drawings) on the substrate until reaching a bottom oxide layer (not shown in the drawing) underneath to form the corresponding fin-shaped structures.

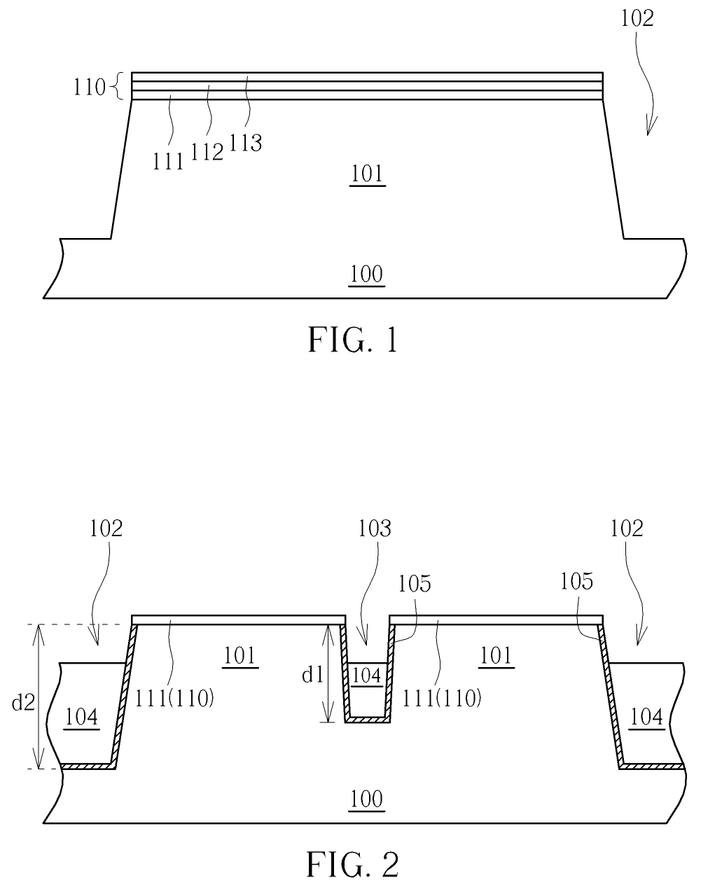

Next, as shown in FIG. 2, another fin cut process is performed through the patterned mask 110, to remove a portion of the fin shaped structures 101 by using an etching process, and to form a trench 103 in the substrate 100. Please note that the trench 103 has a depth d1 less than that of the shallow trench 102. For example, the depth d1 of the trench 103 may be 500 angstroms to 900 angstroms, and a depth d2 of the shallow trench 102 may be 900 angstroms to 1200 angstroms, but not limited thereto. In other words, in one embodiment, the formation of the trench 103 may be integrated with a general fin cut process to form the desired layout or to remove unnecessary portions of the fin shaped structures while the trench 103 is formed. Otherwise, in another embodiment, the trench 103 and the shallow trench 102 may also be formed simultaneously through a double patterning or a multiple patterning process, by using photolithography-photolithography-etch (2P1E) steps, or photolithography-etch-photolithography-etch (2P2E) steps, but not limited thereto.

In the following, an insulating material layer (not shown in the drawings) is formed on the substrate 100, preferably through a flowable chemical vapor deposition (FCVD) process, and a chemical mechanical polishing (CMP) process and an etching back process are then performed, to form an insulating layer 104, such as silicon oxide, in the shallow trench 102 and the trench 103. Through the aforementioned steps, the fin shaped structures 101 may include a portion protruded from the insulating layer 104, such that, the insulating layer 104 formed in the shallow trench 102 may be function as a shallow trench isolation (STI). It is noted that, in one embodiment, a portion of the patterned mask 110 (such as the silicon nitride layer 112 and the silicon oxide layer 113) may be removed selectively while the chemical mechanical polishing process and the etching back process are performed, due to different structural characteristics of tri-gate transistor device or dual-gate transistor device formed subsequently, as shown in FIG. 2. However, the present invention is not limited thereto, and in another embodiment, the patterned mask 110 may also be completely removed or retained selectively. Also, in another embodiment, a dielectric layer may be formed entirely before the insulating layer 104 is formed, to function as a liner 105, covering the substrate 100 and the fin shaped structures 101. The liner 105 may include a monolayer structure or multilayer structure, and preferably includes silicon oxide or suitable high dielectric constant materials. The method of forming the liner 105 may include using an in situ steam generation (ISSG) process to uniformly form the liner 105 on exposed surfaces of the fin shaped structures 101, the shallow trench 102 and the trench 103, as shown in FIG. 2, but not limited thereto. In another embodiment, the liner 105 may also be formed through an atomic layer deposition (ALD) process, or include other dielectric materials.

Next, as shown in FIG. 3 and FIG. 4, the patterned mask 110 (namely, the silicon oxide layer 111) is completely removed, and at least one dummy gate structure, 130, 150 is formed, across the fin shaped structures 101. In the present embodiment, the formation of the dummy gate structures 130, 150 may be integrated with a general gate forming process. For example, a gate forming process may be performed, which includes sequentially forming a gate dielectric material layer (not shown in the drawings), such as including an insulating material (e.g. silicon oxide), and a gate layer (not shown in the drawings) on the fin shaped structures 101, and patterning the gate layer and the gate dielectric material layer, and then forming a plurality of gate structures 170, having a gate dielectric layer 171 and a gate electrode 172, and a plurality of dummy gate structures 130, 150, having dielectric layers 131, 151 and gate electrodes 132, 152 respectively. Thus, in one embodiment, the gate electrodes 132, 152 of the dummy gate structures 130, 150 may include polysilicon, but the material thereof is not limited thereto and may be further modified according to the practical requirements. Subsequently, spacers 133, 153, 173 which surround the dummy gate structures 130, 150 and the gate structure 170 are formed, wherein the spacer 133, 153, 173 may include silicon nitride, silicon oxynitride or silicon carbonitride.

It is worth mentioning that, the dummy gate structure 130 across two adjacent fin shaped structures 101 and the trench 103, and the dummy gate structure 150 across one single fin shape structure 101 and a portion of the shallow trench isolation (namely, the insulating layer 104 formed in the shallow trench 102) are formed simultaneously, such that the dummy gate structures 130, 150 may have the gate electrode 132, 152 being thereof partially covering on the fin shaped structures 101, as shown in FIG. 3. Among them, since the gate electrode 132 of the dummy gate structure 130 covers both on the two adjacent fin shaped structures 101 at two sides of the trench 103, the gate electrode 132 of the dummy gate structure 130 may perform like a “T” shaped. In other words, a portion of the gate dielectric layer 131 and a portion of the gate electrode 132 are disposed in the trench 103, and on the insulating layer 104 formed in the trench 103, as shown in FIG. 3. With such arrangement, it is sufficient to utilize such dummy gate structure 130 and the spacer 133 covering on etched edges of the fin shaped structure 101 to avoid the fin shaped structure 101 being affected in the following forming process, such as source/drain epitaxial growing process, and to keep from structural deformation, current leakage or defects of entire electrical performance. Also, in another embodiment, a width of the gate electrode (not shown in the drawings) of the dummy gate structure 130 may be further controlled to make the gate electrode completely or partially overlapping with the trench 103 such that only the spacer 133 covers on the etched edges of the fin shaped structure 101. Otherwise, the gate electrode (not shown in the drawings) of the dummy gate structure 130 may only have one end thereof covering on the etched edges of the fin shaped structure 101 to make the gate electrode to perform like a “L” shaped (not shown in the drawings).

Through the above mentioned steps, the semiconductor device according to the first embodiment of the present invention is obtained. Subsequently, a selective epitaxial growing (SEG) process, a silicidation process, a contact etching stop layer (CESL) process or a replacement metal gate (RMG) process may be performed. Those processes are similar to a conventional forming process of a transistor and will not be further detail herein. Also, people in the art shall easily realize that the semiconductor device of the present invention is not limited to be formed through the aforementioned processes, and may also be formed through other forming methods.

The following description will detail the different embodiments of the semiconductor device and the forming method thereof of the present invention. To simplify the description, the following description will detail the dissimilarities among the different embodiments and the identical features will not be redundantly described. In order to compare the differences between the embodiments easily, the identical components in each of the following embodiments are marked with identical symbols.

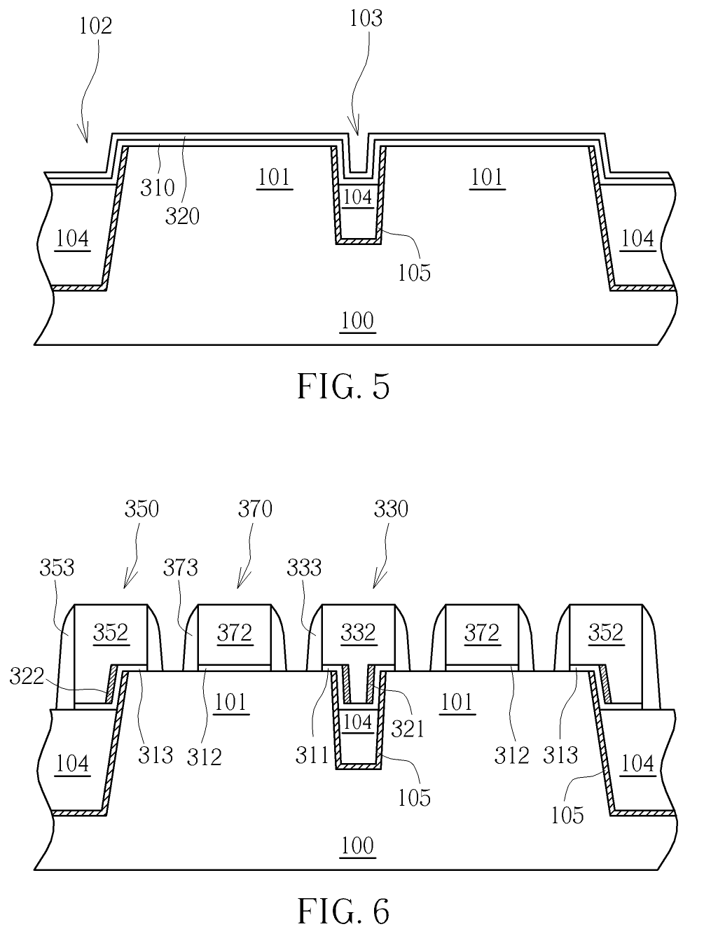

Please refer to FIG. 5 and FIG. 6, which are schematic diagrams illustrating a method of forming a semiconductor device according to the second embodiment of the present invention. The formal steps in the present embodiment are similar to those in the first embodiment, and which includes forming the fin shaped structures 101 and the shallow trench isolation surrounding the fin shaped structures 101 (namely, the insulating layer 104 formed in the shallow trench 102 and the trench 103). However, the differences between the present embodiment and the aforementioned first embodiment are that, after forming the semiconductor structure shown in FIG. 2, the residual patterned mask 110 (namely the silicon oxide layer 111) is removed, and then, an insulating layer 310 and a material layer 320 are formed sequentially, as shown in FIG. 5.

In one embodiment the insulating layer 310 for example includes silicon oxide, and is formed through a deposition process to form the insulating layer 310 on surfaces of the fin shaped structures 101, the shallow trench 102, the trench 103 and the insulating layer 104 formed in the shallow trench 102 and the trench 103, as shown in FIG. 5. However, the formation of the insulating layer 310 is not limited to the aforementioned process, and may also be formed by using a thermal oxidization process in one embodiment, uniformly forming an insulating layer (not shown in the drawings) only on exposed top surfaces of the fin shaped structures 101. Also, in another embodiment, the material layer 320 may include a monolayered or a multilayered structure, and preferably includes silicon oxide, silicon nitride, silicon oxynitride or silicon carbonitride.

Next, an etching process is performed to partially remove the material layer 320 formed on the insulating layer 104 in the trench 103 and the shallow trench 102, and surfaces of the fin shaped structures 101, and then to form spacer layers 321, 322 as shown in FIG. 6. After that, similar to the aforementioned first embodiment, at least one dummy gate structure, 330, 350, a plurality of gate structures 370 and spacers 333, 353, 373 surrounding the dummy gate structures 330, 350 and the gate structures 370 respectively are formed. Among them, the dummy gate structures 330, 350 include patterned insulating layer 310, functioning as gate dielectric layers 311, 313, and gate electrodes 332, 352; each of the gate structures 370 includes a gate dielectric layer 312 (patterned insulating layer 310) and a gate electrode 372. Wherein, the detailed materials and the forming method of the dummy gate structures 330, 350 and the gate structures 370 are all similar to those in the aforementioned first embodiment and will not be further detail herein.

Through the above mentioned steps, the semiconductor device according to the second embodiment of the present invention is obtained. In the present embodiment, it is characterized by additionally forming the monolayered or multilayered spacer layers 321, 322 on sidewalls of the trench 103, to shrink the critical dimension (CD) of the trench 103. It is worth mentioning that, the spacer layer 321 is formed on the insulating layer 104 formed in the trench 103, and covers a portion (a top portion) of the sidewalls of the trench 103 so that the critical dimension of an opening of the trench 103 may be shrunken. In this way, while the dummy gate structure 330 across the trench 103 is formed subsequently, it is ensured that the dummy gate structure 330 may completely cover the etched edges of the two adjacent fin shaped structures 101 and the spacer layer 321. Thus, through the forming method of the present invention it is sufficient to avoid the silicon atoms contained in the sidewalls of the trench 103 being over-consumed by or over-reacted with oxygen provided in the forming process of the insulating layer 104, 310, such as the flowable chemical vapor deposition process or the thermal oxidation process, and also to prevent the critical dimension of the trench opening from getting enlarged to a degree where it cannot be covered by the dummy gate structure because of such over-consumption by or overreaction with oxygen.

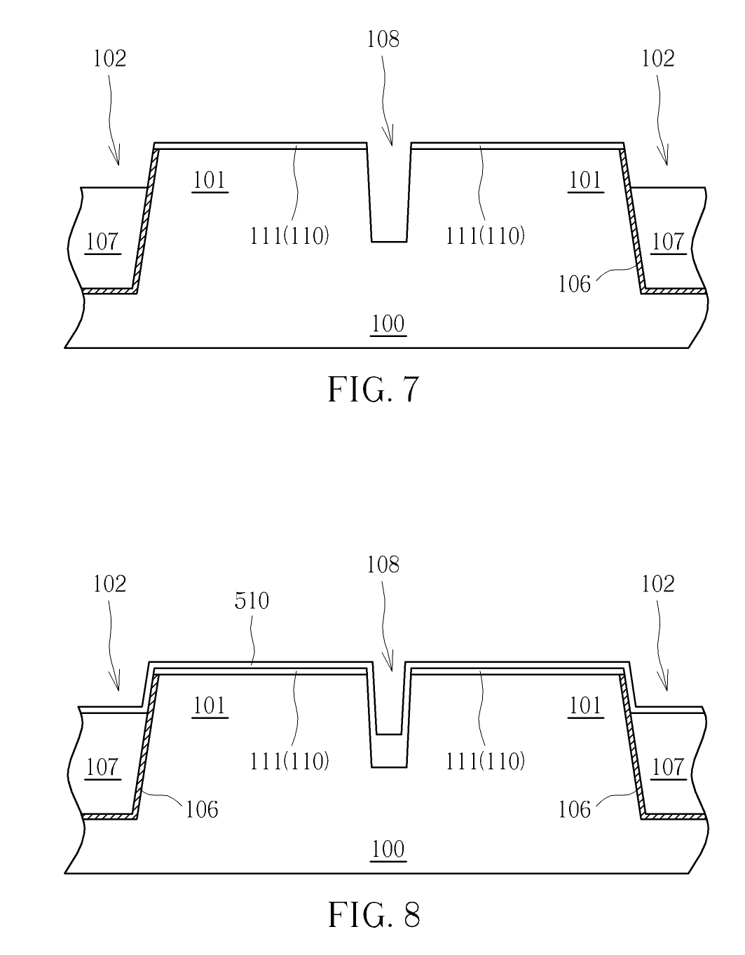

Please refer to FIG. 7 to FIG. 10, which are schematic diagrams illustrating a method of forming a semiconductor device according to the third embodiment of the present invention. The formal steps in the present embodiment are similar to those in the first embodiment, and the differences between the present embodiment and the aforementioned first embodiment are in that, a dielectric layer is formed on the substrate 100 right after the shallow trench 102 is formed in the substrate 100, to function as a liner 106 as shown in FIG. 7. Then, an insulating layer 107 is filled in the shallow trench 102, followed by performing a chemical mechanical polishing process and an etching back process by using the residual patterned mask 110 (such as the silicon oxide layer 111) as a stop layer, thereby making the insulating layer 107 surrounding the fin shaped structures 101 to function as the shallow trench isolation.

Next, another fin cut process is performed to remove a portion of the fin shaped structures 101 through an etching process and form a trench 108 across the fin shaped structures 101, as shown in FIG. 7. Precisely, speaking, the trench 108 is formed for example through additionally forming another patterned mask (not shown in the drawings) on the substrate 100, and transferring the patterns of the patterned mask to the silicon oxide layer 111 and the fin shaped structures 101 in the substrate 100, but not limited thereto.

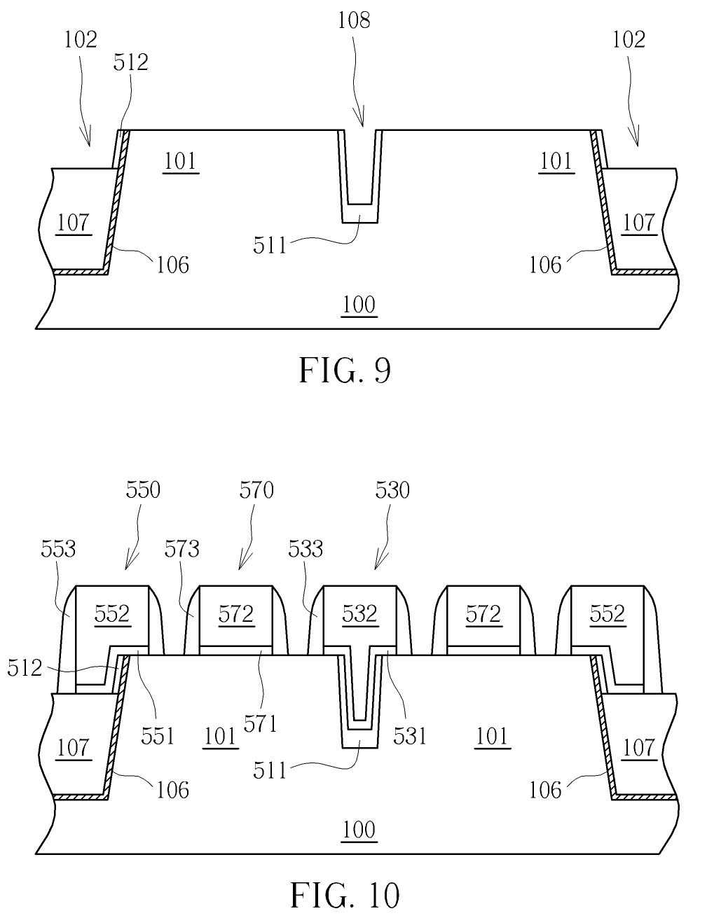

In the following, as shown in FIG. 8 and FIG. 9, spacer layers 511, 512 are formed respectively in the trench 108 and the shallow trench 102. The spacer layers 511, 512 may be formed through a deposition process, which includes entirely forming a material layer 510 shown in FIG. 8 on the substrate 100, to fill in the trench 108 and the shallow trench 102. It is noted that, although being formed on surfaces of the fin shaped structures 101, the trench 108 and the shallow trench 102, the material layer 510 only covers sidewalls and a bottom surface of the trench 108 and the shallow trench 102 without filling to the top of the trench 108 and the shallow trench 102. Also, since the trench 108 has a less depth and width relative to those of the shallow trench 102, the material layer 510 will deposit and form a thick film at the bottom of the trench 108, as shown in FIG. 8. Then, another etching process may be performed to remove the material layer 510 outside the trench 108 and the shallow trench 102. In other words, the etching process is performed by using the silicon oxide layer 111 remaining on the surfaces of the fin shaped structures 101 as a stop layer, to completely remove the material layer 510 formed on the surfaces of the fin shaped structures 101. Meanwhile, the material layer 510 formed on the bottom of the trench 108 may only be partially removed, however, due to having such thick film, to form the spacer layer 511 covering both on the sidewalls and the bottom of the trench 108. Wherein, the detailed materials and other characteristics of the spacer layer 511, 512 may be all similar to those in the second embodiment, and will not be further detailed herein.

After that, similar to the aforementioned first embodiment, at least one dummy gate structure, 530, 550, a plurality of gate structures 570 and spacers 533, 553, 573 surrounding the dummy gate structures 530, 550 and the gate structures 570 respectively are formed, as shown in FIG. 10.

Among them, the dummy gate structures 530, 550 include gate dielectric layers 531, 551 and gate electrodes 532, 552; each of the gate structures 570 includes a gate dielectric layer 571 and a gate electrode 572. Wherein, the detailed materials and the forming method of the dummy gate structures 530, 550 and the gate structures 570 are all similar to those in the aforementioned first embodiment and will not be further detail herein.

Through the above mentioned steps, the semiconductor device according to the third embodiment of the present invention is obtained. In the present embodiment, the trench 108 across the fin shaped structures 101 is mainly formed before the shallow trench isolation is formed to avoid silicon atoms contained in the sidewalls being over-consumed by or overreacted with oxygen provided in the forming processes of the shallow trench isolation or the liner 106, such as the flowable chemical vapor deposition process or the thermal oxidation process, and also to prevent the critical dimension of the trench opening from getting enlarged because of such over-consumption by or overreaction with oxygen. Additionally, the forming method of the present invention may selectively form the monolayered or multilayered spacer layer 511 in the trench 108, with the spacer layer 511 only covering the sidewalls and the bottom of the trench 108 without filling the trench 108 full so that the critical dimension of the trench 108 may be further shrunken via such spacer layer 511, to ensure the coverage of the dummy gate structures 530 and the spacer 533 fully covering on the etched edges of two adjacent fin shaped structures 101.

In summary, the semiconductor device and the forming method thereof in the present invention utilizes adjusting the forming time of the trench and selectively forming the spacer layer on the sidewalls of the trench to shrink the critical dimension of the trench such that one single dummy gate structure is allowed to stretch over the etched edges of two adjacent fin shaped structures and the trench between the two adjacent fin shaped structures, thereby dramatically increasing the integration. Through such arrangement, it is sufficient to avoid the critical dimension of the trench opening being enlarged due to overreaction with or over-consumption by oxygen provided in the forming processes of the shallow trench isolation or the dielectric layer, such as the flowable chemical vapor deposition process or the thermal oxidization process.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor device, comprising:
a fin shaped structure disposed on a substrate, wherein the fin shaped structure has a trench;
a spacer layer disposed on sidewalls of the trench; and
a dummy gate structure being across the trench and comprising a portion thereof disposed in the trench.

2. The semiconductor device according to claim 1, further comprising:
a first insulating layer disposed in the trench.

3. The semiconductor device according to claim 2, wherein the spacer layer is disposed on the first insulating layer in the trench.

4. The semiconductor device according to claim 3, wherein the spacer layer only covers a top portion of the sidewalls of the trench.

5. The semiconductor device according to claim 2, further comprising:
a liner disposed on surfaces of the fin shaped structure and the trench, wherein the liner is disposed between the first insulating layer and surfaces of the fin shaped structure and trench.

6. The semiconductor device according to claim 1, further comprising:
a second insulating layer disposed on the fin shaped structure, and the dummy gate structure being disposed on the second insulating layer.

7. The semiconductor device according to claim 1, wherein the spacer layer directly contacts the sidewalls of the trench.

8. The semiconductor device according to claim 1, further comprising:
a shallow trench isolation disposed in the substrate, surrounding the fin shaped structure.

9. The semiconductor device according to claim 8, wherein the shallow trench isolation has a depth greater than a depth of the trench.

10. The semiconductor device according to claim 1, wherein the dummy gate structure further comprises:
a dummy gate electrode disposed on the trench, wherein a portion of the dummy gate electrode is in the trench; and
a dummy spacer disposed on the fin shaped structure, surrounding the dummy gate electrode.

11. A method of forming a semiconductor device, comprising:
providing a plurality of fin shaped structures on a substrate;
forming a plurality of shallow trench isolations in the substrate to surround the fin shaped structures;
removing a portion of the fin shaped structures to form a trench across the fin shaped structures; and
forming a spacer layer on sidewalls of the trench.

12. The method of forming a semiconductor device according to claim 11, further comprising:
forming a first insulating layer in the trench, wherein the spacer layer is formed on the first insulating layer.

13. The method of forming a semiconductor device according to claim 12, wherein the spacer layer only covers a top portion of the sidewalls of the trench.

14. The method of forming a semiconductor device according to claim 12, further comprising:
forming a liner on surfaces of the fin shaped structures and the trench, wherein the liner is formed between the first insulating layer and the surfaces of the fin shaped structures and trench.

15. The method of forming a semiconductor device according to claim 11, wherein the forming of the spacer layer comprises:
forming a material layer on the substrate, to fill in the trench; and
removing a portion of the material layer outside the trench, to form the spacer layer.

16. The method of forming a semiconductor device according to claim 15, wherein the spacer layer completely covers a bottom portion and the sidewalls of the trench.

17. The method of forming a semiconductor device according to claim 11, wherein the forming of the shallow trench isolation comprises:
forming a plurality of shallow trenches on the substrate to define the fin shaped structures, and
forming an insulating material layer filled in the shallow trench to formed the shallow trench isolation.

18. The method of forming a semiconductor device according to claim 17, wherein the trench is formed before the insulating material layer is formed.

19. The method of forming a semiconductor device according to claim 17, wherein the trench is formed after insulating material layer is formed.

20. The method of forming a semiconductor device according to claim 11, further comprising:
forming a dummy gate structure across the trench, wherein a portion of the dummy gate structure is formed in the trench.
